(19) United States
(12) Patent Application Publication
(10) Pub. No.: US 2026/0242981 A1
(43) Pub. Date: Aug. 20, 2026

(54) SILICON CRYSTAL, SILICON CRYSTAL DEFECT TREATMENT METHOD, AND DEFECT CHARACTERIZATION METHOD

(71) Applicants: ZING SEMICONDUCTOR CORPORATION, Shanghai (CN); SHANGHAI INSTITUTE OF MICROSYSTEM AND INFO. TECH., CHINESE ACADEMY OF SCIENCES, Shanghai (CN)

(72) Inventors: Yun LIU, Shanghai (CN); Huan TUO, Shanghai (CN); Xing WEI, Shanghai (CN); Zhongying XUE, Shanghai (CN)

(21) Appl. No.: 19/645,744

(22) Filed: Apr. 13, 2026

Related U.S. Application Data
(63) Continuation of application No. PCT/CN2024/121608, filed on Sep. 27, 2024.

(30) Foreign Application Priority Data
Oct. 12, 2023 (CN) 202311322780.7

(51) Int. Cl. C30B 33/02; C30B 29/06; C30B 33/10

(52) U.S. Cl. CPC C30B 33/02; C30B 29/06; C30B 33/10

(57) ABSTRACT

A silicon crystal, a silicon crystal defect treatment method, and a defect characterization method. The silicon crystal defect treatment method includes: providing a silicon crystal with self-interstitial defects; and executing a rapid heat treatment process on the silicon crystal, so as to at least eliminate self-interstitial defects within a preset distance from a surface of the silicon crystal. By means of executing a rapid heat treatment process on a silicon crystal, self-interstitial defects in the silicon crystal can be quickly and effectively reduced or even completely eliminated.

### CROSS-REFERENCE TO RELATED APPLICATIONS

This application is a continuation application of International Patent Application No. PCT/CN2024/121608, filed with the China National Intellectual Property Administration on Sep. 27, 2024, entitled “Silicon Crystal, Silicon Crystal Defect Treatment Method, and Defect Characterization Method”, which claims the benefits of and priority to Chinese patent application No. 202311322780.7 filed Oct. 12, 2023, entitled “Silicon Crystal, Silicon Crystal Defect Treatment Method, and Defect Characterization Method”, the content of all of which is incorporated herein by reference in their entirety.

### TECHNICAL FIELD

The present invention relates to the field of semiconductor technology and, in particular, to a silicon crystal, a method for dissolving defects in a silicon crystal and a method for characterizing defects.

### BACKGROUND

Single crystal silicon wafers are the most important substrate material in the integrated circuit industry. Limited by the performance of existing growth processes, there are defects in silicon ingots grown using these processes. At present, intrinsic defects that can be found in single crystal silicon are substantially 1) self-interstitials and 2) vacancies. During the growth of a silicon crystal, either a too slow growth rate, or an excessively large temperature gradient, will lead to the presence of numerous self-interstitial atoms in the crystal being grown, which aggregate into self-interstitial defects, such as self-interstitial clusters (type B defects), dislocations (type A defects) and so forth. When the resultant crystal is subsequently used to fabricate devices, such self-interstitial defects may deteriorate the performance of the resulting devices, for example, due to increased leakage, a lower breakdown voltage or the like. In particular, self-interstitial defects are extremely difficult to eliminate due to the limited capabilities of existing processes. Therefore, effectively eliminating self-interstitial defects in silicon crystals is of particular significance.

A method for reducing intrinsic dislocations in a heavily boron-doped Czochralski (Cz) silicon wafer, which has been disclosed in the art, includes placing the heavily boron-doped Czochralski (Cz) silicon wafer in an atmosphere of 99.99% or more pure argon at 1000 to 1100° C. for 1 to 2 hours, followed by natural cooling, wherein the Cz silicon wafer is heavily doped with boron at a concentration of 7×10¹⁹ cm⁻³ to 1.1×10²⁰ cm⁻³. This technique has the advantages of a simple process, easy operation, ability to rapidly and effectively reduce, or even eliminate, intrinsic dislocations in a heavily boron-doped Cz silicon wafer and hence improve its quality, and particular applicability to Cz silicon wafers heavily doped with boron at a concentration in the range of from 7×10¹⁹ cm⁻³ to 1.1×10²⁰ cm⁻³. Despite such good performance in removing intrinsic dislocations from a heavily boron-doped Cz silicon wafer, it requires doping with boron at a concentration of 7×10¹⁹ cm⁻³ to 1.1×10²⁰ cm⁻³ and is therefore somewhat limited in application. Moreover, this method does not show comparably good performance for other types of silicon wafers, such as lightly boron-doped silicon wafers, float-zone (FZ) silicon wafers, etc. and imposes certain requirements on the thermal processing atmosphere. Therefore, there is a need for a more generally applicable method for removing self-interstitial defects from a silicon crystal.

### SUMMARY

The present invention seeks to solve the problem of rapidly and effectively reducing, or even eliminating, self-interstitial defects in a single silicon crystal by presenting a silicon crystal, a method for dissolving defects in a silicon crystal and a method for characterizing defects.

To this end, the present invention provides a method for dissolving defects in a silicon crystal, which includes:
providing the silicon crystal with self-interstitial defects; and
performing a rapid thermal process on the silicon crystal to at least eliminate those of the self-interstitial defects located within a predefined distance from surfaces of the silicon crystal.

Optionally, the rapid thermal process may include an annealing stage, which is performed at a temperature in the range of 1100° C. to 1350° C. for a duration ranging from 10 seconds to 240 seconds in a mixed argon-nitrogen atmosphere, a pure argon atmosphere or a pure nitrogen atmosphere.

Optionally, the annealing stage may be performed at a temperature in the range of 1175° C. to 1350° C.

Optionally, the annealing stage may be performed for a duration ranging from 80 seconds to 160 seconds.

Optionally, the rapid thermal process may further include a heating stage, which is performed prior to the annealing stage at a heating rate greater than 1° C./s in a pure argon atmosphere or a mixed argon-nitrogen atmosphere, wherein nitrogen is present in the mixed atmosphere in an amount greater than 1% by volume.

Optionally, the rapid thermal process may further include a loading stage, which is performed prior to the heating stage at a temperature of 400° C. to 800° C. in an atmosphere of pure argon introduced within a period of time of 0.1 to 10 minutes.

Optionally, the rapid thermal process may be performed either at the atmospheric pressure, or at a reduced pressure of 1 torr to 100 torr.

Optionally, nitride or oxide layers, which are formed on the surfaces of the silicon crystal during the rapid thermal process, may be removed using a hydrofluoric acid solution after the rapid thermal process is completed.

The present invention also provides a method for characterizing defects, which belongs to the same inventive concept as the method as defined above and is used for a silicon crystal having been treated with the above method. The characterizing method includes: exposing self-interstitial defects in the silicon crystal by dry or wet etching; and optically characterizing the self-interstitial defects in the silicon crystal.

The present invention also provides a silicon crystal, which belongs to the same inventive concept as the methods as defined above and has been treated with the dissolving method, and in which there are no self-interstitial defects within a predefined distance from surfaces of the silicon crystal.

### BRIEF DESCRIPTION OF THE DRAWINGS

Those of ordinary skill in the art will understand that the following drawings are presented to enable a better understanding of the present invention and not intended to limit the scope thereof in any sense, in which:

FIG. 1 shows a flowchart of a method for dissolving defects in a silicon crystal, according to an embodiment of the present invention;

FIGS. 2 to 6 schematically illustrate distributions of self-interstitial defects in silicon crystals in a first experiment, according to an embodiment of the present invention;

FIG. 7 shows a histogram of self-interstitial defects in the silicon crystals of the first experiment, according to an embodiment of the present invention;

FIGS. 8 to 9 schematically illustrate distributions of self-interstitial defects in silicon crystals in a second experiment, according to an embodiment of the present invention;

FIG. 10 shows a histogram of self-interstitial defects in the silicon crystals in the second experiment, according to an embodiment of the present invention;

FIGS. 11 to 12 schematically illustrate distributions of self-interstitial defects in silicon crystals in a third experiment, according to an embodiment of the present invention; and

FIG. 13 shows a histogram of self-interstitial defects in the silicon crystals in the third experiment, according to an embodiment of the present invention.

In these figures, 10 denotes a silicon crystal, and 10a represents a self-interstitial defect.

### DETAILED DESCRIPTION

FIG. 1 shows a flowchart of a method for dissolving defects in a silicon crystal according to an embodiment of the present invention. As shown in FIG. 1, the method includes the steps of:
S10) providing the silicon crystal with self-interstitial defects; and
S20) eliminating at least those of the self-interstitial defects within a predefined distance from surfaces of the silicon crystal by performing a rapid thermal process on the silicon crystal.

In step S10, the silicon crystal may be, for example, a single silicon crystal with self-interstitial defects. Specifically, during the growth of such a single silicon crystal, either a too slow growth rate, or an excessively large temperature gradient, will lead to the presence of numerous self-interstitial atoms in the crystal being grown, which aggregate into self-interstitial defects including both those of type A (e.g., dislocations) and those of type B (e.g., self-interstitial clusters). A-defects are large in size, structurally stable at high temperatures, and generally difficult to eliminate. B defects are small in size, unstable in structure at high temperatures, and easy to eliminate. This invention mainly focuses on eliminating A-defects.

In step S20, the rapid thermal process may include sequential loading, heating and annealing stages. Prior to the heating stage, the loading stage may be performed for example, at a temperature of 400° C. to 800° C., preferably such as 600° C., in an atmosphere of, for example, pure argon introduced over a period of, for example, 0.1 to 10 minutes, preferably such as 1 minute, in order to allow the silicon crystal to be loaded into a rapid thermal annealing (RTA) furnace. The RTA furnace may be generally filled with argon during its standby, which can provide protection for the furnace. The loading stage is followed by the heating stage, in which the loaded silicon crystal may be heated instead in a mixed atmosphere of argon and nitrogen. In the heating stage, nitrogen may be present in the mixed argon-nitrogen atmosphere in an amount of n % by volume, where n>1. That is, nitrogen is present in an amount of greater than 1% by volume in the mixed atmosphere used in the heating stage. The heating stage may be performed at a heating rate of greater than 1° C./s. After a desired temperature is reached, the annealing stage is commenced optionally still in the mixed Ar/N₂ (n %) atmosphere that has been used in the heating stage, or instead in an atmosphere of pure argon or pure nitrogen. That is, the annealing stage may be performed in an atmosphere of an argon-nitrogen mixture, pure argon or pure nitrogen. The annealing stage may be performed at a temperature, for example, in the range of 1100° C. to 1350° C., preferably 1175° C. to 1350° C., for a period of, for example, 10 to 240 seconds, preferably 80 to 160 seconds. The rapid thermal process may be carried out either at the atmospheric pressure, or at a reduced pressure of, for example, 1 to 100 torr, preferably 15 torr.

After the rapid thermal process, more precisely, the annealing stage, is completed, the RTA furnace is instead filled with pure argon and cooled to a standby temperature of 400° C. to 800° C., preferably 500° C., at a rate of at least greater than 5° C./s.

In the rapid thermal process, nitride and oxide layers may be formed on surfaces of the silicon crystal, which need to be removed after the process is completed. The removal may be accomplished by using a hydrofluoric acid solution at a concentration of lower than 20%, preferably 5%.

As a result of the rapid thermal process in step S20, at least self-interstitial defects within a predefined distance from surfaces of the silicon crystal are eliminated, i.e., within regions immediately beneath the surfaces. The surfaces of the silicon crystal may include its upper and lower surfaces. For example, the predefined distance may be less than 20 μm, preferably 1 to 10 μm, more preferably 1 to 5 μm.

Embodiments disclosed herein also provide a method for characterizing defects in a silicon crystal that has been dissolved according to a method as defined above, which includes exposing self-interstitial defects in the silicon crystal by dry or wet etching; and then optically characterizing the self-interstitial defects in the silicon crystal. In particular, the dry etching may be accomplished, for example, by using a gas, and the wet etching may be accomplished, for example, by using a buffered solution containing nitric acid, hydrofluoric acid and acetic acid. The optical characterization of the self-interstitial defects may be accomplished, for example, using a laser scattering approach involving computationally locating convexities or concavities in the silicon crystal and determining an equivalent size of them through scanning the surfaces of the silicon crystal.

Embodiments disclosed herein also provide a silicon crystal, which has been dissolved according to a method as defined above so as to be absent of self-interstitial defects within a predefined distance from its surfaces. The silicon crystal may be a P- or N-type silicon crystal obtained by zone melting or the Cz method. The silicon crystal contained intrinsic self-interstitial defects as obtained, of which those within the predefined distance from the surfaces have been eliminated by subjecting the silicon crystal to a rapid thermal process. It should be noted that the predefined distance is measured normally to an upper or lower surface of the silicon crystal and may be, for example, less than 20 μm, preferably 1 to 10 μm, more preferably 1 to 5 μm.

TABLE 1
Conditions of First Experiment

| | | Annealing | Annealing |
|---|---|---|---|
| | Temperature | Duration | Atmosphere |
| Silicon Wafer 1 | / | / | / |
| Silicon Wafer 2 | 1250° C. | 20 s | Pure Oxygen |
| Silicon Wafer 3 | | | Pure Argon |
| Silicon Wafer 4 | | | Argon + 5% Nitrogen |
| Silicon Wafer 5 | | | Pure Nitrogen |

As shown in Table 1, the inventors have conducted a verification experiment on five silicon wafers: Silicon Wafer 1, taken as a control wafer not subjected to any rapid thermal process; and Silicon Wafers 2 to 5, as experimental wafers each subjected to a rapid thermal process including a heating stage performed in a mixed argon-nitrogen (5%) atmosphere and an annealing stage performed in an oxygen, mixed argon-nitrogen (5%), pure argon or pure nitrogen atmosphere. In other words, Silicon Wafers 2 to 5 undergo rapid thermal processes performed in distinct annealing atmospheres—Silicon Wafer 2 to pure oxygen, Silicon Wafer 3 to pure argon, Silicon Wafer 4 to argon mixed with nitrogen (5%), and Silicon Wafer 4 to pure nitrogen. The rapid thermal processes on Silicon Wafers 2 to 5 are carried out at the same temperature (1250° C.) for the same period of time (20 seconds).

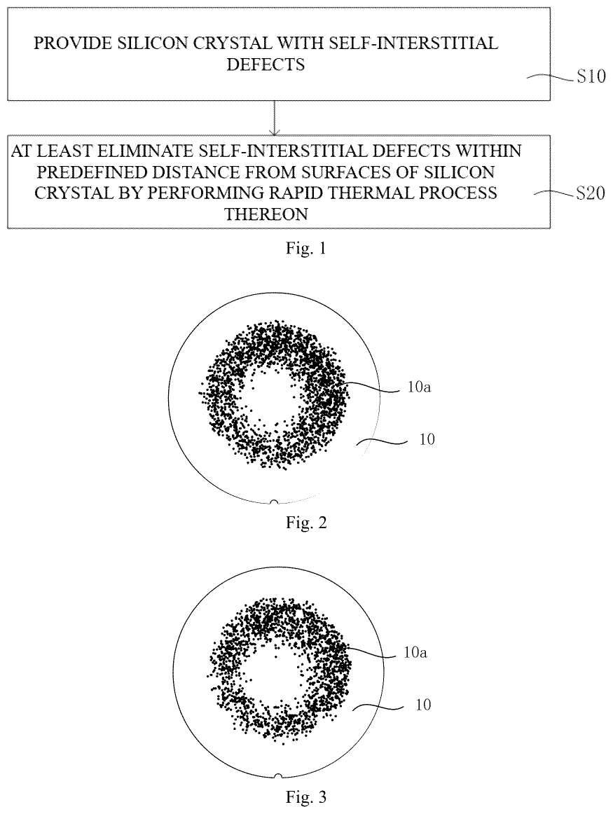

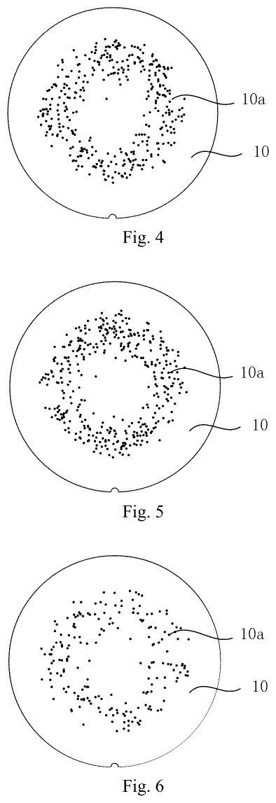

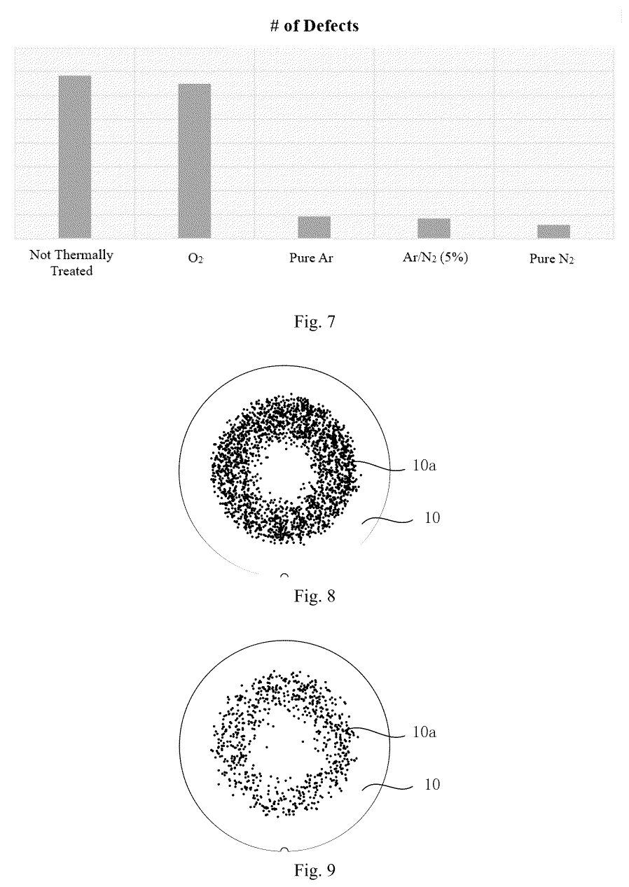

FIGS. 2 to 6 schematically illustrate distributions of self-interstitial defects in the silicon crystals in the first experiment. FIG. 7 shows a histogram of self-interstitial defects in the silicon crystals in the first experiment. The distributions are obtained by optically characterizing the silicon crystals that have undergone the experiment. Specifically, FIG. 2 schematically illustrates a distribution of self-interstitial defects in Silicon Wafer 1, FIG. 3 schematically illustrates a distribution of self-interstitial defects in Silicon Wafer 2, FIG. 4 schematically illustrates a distribution of self-interstitial defects in Silicon Wafer 3, FIG. 5 schematically illustrates a distribution of self-interstitial defects in Silicon Wafer 4, and FIG. 6 schematically illustrates a distribution of self-interstitial defects in Silicon Wafer 5. Bins in the histogram of FIG. 7 represent estimates of the numbers of self-interstitial defects in the silicon crystals dissolved under different conditions in the experiment, from which the results of self-interstitial defect elimination can be clearly seen. As revealed by a comparison made between FIG. 2 and FIGS. 3 to 6, and as can be seen from FIG. 7, dissolving the silicon crystal 10 in the oxygen atmosphere shows almost no effect of reducing the number of self-interstitial defects 10a therein, whilst those dissolved in the mixed argon-nitrogen (5%), pure argon and pure nitrogen atmospheres all exhibit an effective reduction of such defects. Further, the number of self-interstitial defects in Silicon Wafer 5 dissolved in the pure nitrogen atmosphere is less than those of Silicon Wafers 4 and 3 dissolved in the mixed argon-nitrogen and pure argon atmospheres, respectively. This is because a high temperature creates vacancy-self interstitial atom pairs in the silicon crystals, and since the self-interstitial atoms diffuse faster than the vacancies, there are residual vacancies in the silicon crystals, which bind self-interstitial defects at the high temperature, thus eliminating these self-interstitial defects. The different results are obtained in the different atmospheres due to the reasons as explained below. The treatment in the oxygen atmosphere oxidizes surfaces of the silicon crystal, injecting self-interstitial atoms deeper into the silicon crystal. The injected self-interstitial atoms compound with residual vacancies near the surfaces, making them impossible to eliminate self-interstitial defects. On the contrary, the treatment in the nitrogen atmosphere azotizes surfaces of the silicon crystal, injecting vacancies deeper into the silicon crystal. As a result, more concentrated vacancies are present in the silicon crystal near the surfaces, facilitating elimination of self-interstitial defects in regions immediately beneath the surfaces. The treatment in the argon atmosphere relies on only residual vacancies generated at the high temperature for elimination of self-interstitial defects and is therefore inferior in performance to the treatment in the nitrogen atmosphere. Therefore, increased presence of nitrogen means more vacancies being injected to regions of the silicon crystal immediately beneath its surfaces, which can eliminate more self-interstitial defects. This explains even fewer self-interstitial defects in Silicon Wafer 5 dissolved in the pure nitrogen atmosphere.

TABLE 2
Conditions of Second Experiment

| | | Annealing | Annealing |
|---|---|---|---|
| | Temperature | Duration | Atmosphere |
| Silicon Wafer 5 | 1250° C. | 20 s | Pure Nitrogen |
| Silicon Wafer 6 | 1100° C. | | |
| Silicon Wafer 7 | 1000° C. | | |

As shown in Table 2, the inventors have conducted another verification experiment, in accordance with a further embodiment. Based on the results of the above discussed experiment, three silicon crystals with self-interstitial defects similar to those of the above experiment are chosen for this experiment, i.e., Silicon Wafers 5 to 7. One of the wafers is subjected to the same experimental conditions as Silicon Wafer 5 in the above experiment, and the other two (Silicon Wafers 6 and 7) are subjected to respective new experimental conditions. Specifically, Silicon Wafers 6 and 7 are annealed in the same atmosphere (pure nitrogen) for the same period of time (20 seconds), as Silicon Wafer 5, but at different temperatures both lower than that for Silicon Wafer 5. For example, Silicon Wafer 6 is annealed at 1100° C., and Silicon Wafer 7 at 1000° C.

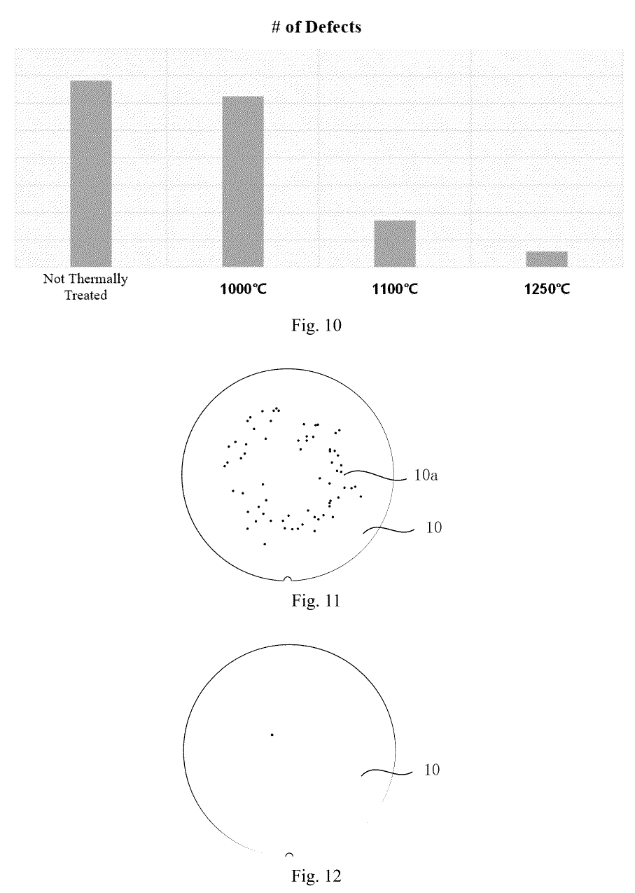

FIGS. 8 to 9 schematically illustrate distributions of self-interstitial defects in silicon crystals in the second experiment. FIG. 10 shows a histogram of self-interstitial defects in the silicon crystals in the second experiment. The distributions are obtained by optically characterizing the silicon crystals that have undergone the experiment. Specifically, FIG. 8 schematically illustrates a distribution of self-interstitial defects in Silicon Wafer 6, and FIG. 9 schematically illustrates a distribution of self-interstitial defects in Silicon Wafer 7. Bins in the histogram of FIG. 10 represent estimates of the numbers of self-interstitial defects in the silicon crystals dissolved under different conditions in the experiment, from which the results of self-interstitial defect elimination can be clearly seen. As revealed by a comparison made between FIG. 6 for the first experiment and FIGS. 8 and 9 for the second experiment, and as can be seen from FIG. 10, annealing a silicon crystal 10 in pure nitrogen for 20 seconds at an increased annealing temperature enables enhanced or even complete removal of self-interstitial defects 10a from the crystal. As shown in FIG. 6, there are substantially no self-interstitial defects 10a remaining in the silicon crystal 10. This is because a high temperature creates vacancy-self interstitial atom pairs in the silicon crystal, and since the self-interstitial atoms diffuse faster than the vacancies, there are residual vacancies in the silicon crystal, which bind self-interstitial defects at the high temperature, thus eliminating these self-interstitial defects. Accordingly, annealing a silicon crystal 10 at a higher temperature enables better removal of self-interstitial defects 10a therefrom.

TABLE 3
Conditions of Third Experiment

| | | Annealing | Annealing |
|---|---|---|---|
| | Temperature | Duration | Atmosphere |
| Silicon Wafer 5 | 1250° C. | 20 s | Pure Nitrogen |
| Silicon Wafer 8 | | 60 s | |
| Silicon Wafer 9 | | 90 s | |

As shown in Table 3, the inventors have conducted yet another verification experiment, in accordance with a further embodiment. Based on the results of the above discussed experiment, three silicon crystals with self-interstitial defects similar to those of the above experiment are chosen for this experiment, i.e., Silicon Wafers 5 and 8 to 9. One of the wafers is subjected to the same experimental condition as Silicon Wafer 5 in the above experiment, and the other two (Silicon Wafers 8 and 9) are subjected to respective new experimental conditions. Specifically, Silicon Wafers 8 and 9 are annealed at the same temperature (1250° C.) in the same atmosphere (pure nitrogen), as Silicon Wafer 5, but for different periods of time both longer than that for Silicon Wafer 5. For example, Silicon Wafer 8 is annealed for 60 seconds, and Silicon Wafer 9 for 90 seconds.

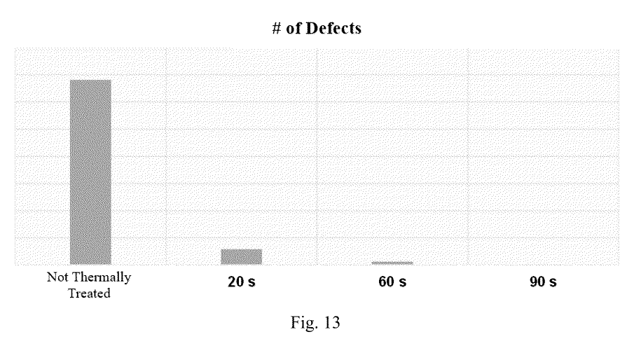

FIGS. 11 to 12 schematically illustrate distributions of self-interstitial defects in silicon crystals in the third experiment. FIG. 13 shows a histogram of self-interstitial defects in the silicon crystals in the third experiment. The distributions are obtained by optically characterizing the silicon crystals that have undergone the experiment.

Specifically, FIG. 11 schematically illustrates a distribution of self-interstitial defects in Silicon Wafer 8, and FIG. 12 schematically illustrates a distribution of self-interstitial defects in Silicon Wafer 9. Bins in the histogram of FIG. 13 represent estimates of the numbers of self-interstitial defects in the silicon crystals dissolved under different conditions in the experiment, from which the results of self-interstitial defect elimination can be clearly seen. As revealed by a comparison made between FIG. 6 for the first experiment and FIGS. 11 and 12 for the third experiment, and as can be seen from FIG. 13, annealing a silicon crystal 10 in pure nitrogen at 1250° C. for an extended period of time enables enhanced or even complete removal of self-interstitial defects 10a from the crystal. As shown in FIG. 8, there are substantially no self-interstitial defects 10a remaining in the silicon crystal 10. This is because a high temperature creates vacancy-self interstitial atom pairs in the silicon crystal, and since the self-interstitial atoms diffuse faster than the vacancies, there are residual vacancies in the silicon crystal, which bind self-interstitial defects at the high temperature, thus eliminating these self-interstitial defects. Accordingly, annealing a silicon crystal 10 at a high temperature for a longer period of time enables enhanced or even complete removal of self-interstitial defects 10a therefrom.

In summary, embodiments disclosed herein provide a silicon crystal, a method for dissolving defects in a silicon crystal and a method for characterizing defects. The treatment is accomplished by a rapid thermal process, which has eliminated at least self-interstitial defects, including those of types A and B, within a predefined distance from surfaces of the silicon crystal. Experiments have been conducted to verify the performance of the process in removing self-interstitial defects at different annealing temperatures, durations and atmospheres. The results show that better removal of self-interstitial defects can be obtained both at an increased annealing temperature and at an extended annealing duration. Moreover, when a silicon crystal is dissolved in a nitrogen atmosphere, its surfaces will be azotized, injecting vacancies deeper into the silicon crystal. As a result, more concentrated vacancies are present in the silicon crystal near the surfaces, facilitating elimination of self-interstitial defects in regions immediately beneath the surfaces. According to the results of the experiments conducted in accordance with embodiments disclosed herein, self-interstitial defects in a silicon crystal can be rapidly and effectively reduced, or even completely eliminated, when it is annealed in an mixed argon-nitrogen atmosphere, pure argon or pure nitrogen atmosphere at a temperature in the range of 1100° C. to 1350° C. for a period of 10 seconds to 240 seconds. Even better removal of self-interstitial defects from the silicon crystal can be achieved when the annealing is carried out at a temperature in the range of 1175° C. to 1350° C. for a period of 80 seconds to 160 seconds.

1. A method for dissolving silicon crystal defects, comprising:
providing a silicon crystal with self-interstitial defects; and
performing a rapid thermal process on the silicon crystal to at least eliminate those of the self-interstitial defects located within a predefined distance from surfaces of the silicon crystal.

2. The method for dissolving the silicon crystal defects according to claim 1, wherein the rapid thermal process comprises an annealing stage, wherein the annealing stage is performed at a temperature in the range of 1100° C. to 1350° C. for a duration ranging from 10 seconds to 240 seconds, and wherein the annealing stage is performed in a mixed argon-nitrogen atmosphere, a pure argon atmosphere or a pure nitrogen atmosphere.

3. The method for dissolving the silicon crystal defects according to claim 2, wherein the annealing stage is performed at a temperature in the range of 1175° C. to 1350° C.

4. The method for dissolving the silicon crystal defects according to claim 2, wherein the annealing stage is performed for a duration ranging from 80 seconds to 160 seconds.

5. The method for dissolving the silicon crystal defects according to claim 2, wherein the rapid thermal process further comprises a heating stage, the heating stage is performed prior to the annealing stage, the heating stage is performed at a heating rate greater than 1° C./s, the heating stage is performed in a pure argon atmosphere or a mixed argon-nitrogen atmosphere, and wherein nitrogen is present in the mixed atmosphere in an amount greater than 1% by volume.

6. The method for dissolving the silicon crystal defects according to claim 5, wherein the rapid thermal process further comprises a loading stage, the loading stage is performed prior to the heating stage, the loading stage is performed at a temperature of 400° C. to 800° C., the loading stage is performed in an atmosphere of pure argon introduced within a period of time of 0.1 to 10 minutes.

7. The method for dissolving the silicon crystal defects according to claim 1, wherein the rapid thermal process is performed either at the atmospheric pressure, or at a reduced pressure, the reduced pressure is of 1 torr to 100 torr.

8. The method for dissolving the silicon crystal defects according to claim 1, wherein a nitride layer or an oxide layer is formed on the surfaces of the silicon crystal during the rapid thermal process, and wherein after the rapid thermal process is completed, a hydrofluoric acid solution is used to remove the nitride layer or the oxide layer on the surfaces of the silicon crystal.

9. The method for dissolving the silicon crystal defects according to claim 1, wherein the predefined distance from the surfaces of the silicon crystal is less than 20 μm.

10. The method for dissolving the silicon crystal defects according to claim 9, wherein the predefined distance from the surfaces of the silicon crystal ranges from 1 μm to 10 μm.

11. The method for dissolving the silicon crystal defects according to claim 10, wherein the predefined distance from the surfaces of the silicon crystal ranges from 1 μm to 5 μm.

12. A method for characterizing defects, characterized by being used for a silicon crystal, which has been treated with the method for dissolving the silicon crystal defects according to claim 1, and comprising: first exposing self-interstitial defects in the silicon crystal by dry or wet etching; and then using an optical detection method to characterize the self-interstitial defects in the silicon crystal.

13. A silicon crystal, characterized by having been treated with the method for dissolving the silicon crystal defects according to claim 1, wherein there are no self-interstitial defects within a predefined distance from the surfaces of the silicon crystal.
